(19) United States
(12) Patent Application Publication
(10) Pub. No.: US 2008/0156266 A1
(43) Pub. Date: Jul. 3, 2008

(54) Plasma processing apparatus

(75) Inventors: Naoko Yamamoto, Osaka-shi (JP); Koji Murakami, Soraku-gun (JP); Syuichi Kitamura, Sakurai-shi (JP)

Correspondence Address: Edwards Angell Palmer & Dodge LLP, P.O. Box 55874, Boston, MA, 02205, US

(73) Assignee: Sharp Kabushiki Kaisha, Osaka (JP)

(21) Appl. No.: 11/999,731

(22) Filed: Dec. 6, 2007

(30) Foreign Application Priority Data
Dec. 7, 2006 (JP) 2006-330875(P)

(51) Int. Cl. C23C 16/513

(52) U.S. Cl. 118/723 R

(57) ABSTRACT

A clearance between a metal electrode and a sidewall portion (sidewall) of an approximately U-shaped dielectric is adjusted by, for example, partially inserting a heat insulator, a heat shield or an insulating material. Temperature difference in the Z direction (vertical direction) of the sidewall portion of approximately U-shaped dielectric is made smaller than temperature difference between front and rear sides at the bottom (bottom portion) of approximately U-shaped dielectric, to reduce warp in the Z direction of the sidewall portion of approximately U-shaped dielectric. This curbs warp in the Z direction of the bottom portion of approximately U-shaped dielectric coupled to the sidewall portion. The warp in the Z direction, which would be generated if the temperature difference only between the front and rear surfaces at the bottom were considered, can be curbed by utilizing the sidewall portion of approximately U-shaped dielectric.

This nonprovisional application is based on Japanese Patent Applications Nos. 2005-356256 and 2006-330875 filed with the Japan Patent Office on Dec. 9, 2005 and Dec. 7, 2006, respectively, the entire contents of which are hereby incorporated by reference.

### BACKGROUND OF THE INVENTION

1. Field of the Invention

The present invention relates to a plasma processing apparatus for thin film formation and processing, as well as for surface processing. More specifically, it relates to a plasma processing apparatus generating plasma for plasma-processing a substrate.

2. Description of the Background Art

A plasma processing apparatus for various plasma processing including etching, film formation, ashing and surface processing is used in manufacturing various electronic devices, such as semiconductors, flat-panel displays and solar cells. Among the devices mentioned above, devices such as a flat-panel display and a thin-film solar cell using a thin-film amorphous silicon process an object such as a substrate having the size as large as 2 m or larger, in order to meet the demand for larger size and smaller manufacturing cost and, accordingly, the plasma processing apparatus also comes to have larger size.

Most of the plasma processing apparatuses uses high-frequency power source of RF band or VHF band as a power source for plasma generation, in view of speed of processing and process quality. By way of example, a plasma processing apparatus processing a substrate whose one side is 2 m requires an electrode of corresponding size, with at least one side being longer than 2 m.

In the plasma processing apparatus as described above, it has been a common practice to use plasma under reduced pressure. Recently, however, plasma processing apparatuses performing plasma processing at or around the atmospheric pressure have come to be practically used. The plasma processing apparatus performing plasma processing at or around the atmospheric pressure does not require any vacuum vessel and, hence, allows reduction in size. Further, as the active species of plasma have high density, speed of processing can be increased. Further, dependent on the structure of the apparatus, the processing time per one substrate as the object of processing can advantageously be made almost equal to the time of plasma processing. On the other hand, if the supplied electric power is increased to attain higher speed of processing, arc discharge occurs if a metal electrode portion is exposed at the surface. Therefore, generally, the surface of metal electrode is covered with solid dielectric. When such electrodes having metal electrodes covered with solid dielectric are placed opposite to each other and a high voltage is applied, plasma generates between the solid dielectrics. If there is a clearance of several tens nm or larger between the metal electrode and the solid dielectric covering the metal electrode, however, an abnormal discharge may possibly occur in the clearance.

This problem is addressed, for example, in Japanese Patent Laying-Open No. 2005-019150, which discloses a method of supporting a dielectric to eliminate the clearance, in order to prevent abnormal discharge in the clearance between the metal electrode and the solid dielectric. A method of filling the clearance between the metal electrode and the dielectric by an adhesive is also disclosed. Metal and dielectric have different coefficients of linear expansion and different amounts of rise in temperature and, therefore, it is difficult to attain equal amount of thermal expansion. As a result, there is a possibility of peeling at the adhered portion. In connection with this point, Japanese Patent Laying-Open No. 2004-288452 discloses a method of adhering the metal electrode and the dielectric, using an adhesive that can absorb the difference in thermal expansion, so as to absorb the difference in thermal expansion between the metal electrode and the dielectric.

When the electrode becomes longer, for example, when the opposing surfaces of the counter electrodes come to be 1 m or longer in one direction, amount of warp caused by temperature difference between the plasma irradiation surface and the opposite surface to be in contact with the metal electrode of the solid electrode poses more serious problem than the amount of thermal expansion in the lengthwise direction. Particularly, when high-pressure plasma represented by an atmospheric pressure plasma is used, the gap between electrodes is as narrow as in the order of several mm, and the gap would possibly fluctuate to an innegligible degree in the lengthwise direction, affecting the process. The same applies to a vacuum plasma processing apparatus having a narrow gap of about 30 mm or smaller between the electrodes. References cited above do not disclose any method of solving such a problem.

### SUMMARY OF THE INVENTION

The present invention was made to solve the above-described problem and its object is to provide a plasma processing apparatus realizing high uniformity, in which amount of warp caused by temperature difference between the plasma irradiated surface and the rear surface on the metal electrode side of the dielectric when plasma generates is reduced as much as possible, whereby even a very small gap of several mm between the electrodes is hardly influenced.

The present invention provides a plasma processing apparatus having two electrode units arranged opposite to each other and processing an object of processing with plasma generated between the two electrode units, wherein at least one of the two electrode units includes a metal electrode, a first dielectric member provided to cover the metal electrode, and cooling means for cooling the first dielectric member. The first dielectric member has a base portion including an opposing surface facing the other electrode unit and a sidewall portion provided to cover, with the base portion, the metal electrode. Thermal resistance between the sidewall portion of the first dielectric member and the cooling means is higher than thermal resistance between the base portion of the dielectric member and the cooling means.

Preferably, the cooling means corresponds to a passage of a cooling medium provided for the metal electrode.

Particularly, between the sidewall portion of the first dielectric member and the opposing metal electrode, a heat insulator is inserted.

Preferably, a clearance between a rear side opposite to the opposing surface at the base portion of the first electrode member and the opposing metal electrode is narrower than a clearance between a surface opposing to the metal electrode of the sidewall portion of the first dielectric member and the metal electrode.

Preferably, the rear side opposite to the opposing surface at the base portion of the first electrode member and the opposing metal electrode are in contact with each other. The surface opposing to the metal electrode of the sidewall portion of the first dielectric member and the metal electrode are not in contact with each other.

Preferably, the first dielectric member has a U-shaped cross section having the base portion and the sidewall portion.

Preferably, the electrode unit further includes a second dielectric member provided to cover, in combination with the first dielectric member, the metal electrode, and a pressing mechanism for pressing the metal electrode to the rear surface opposite to the opposing surface, at the base portion of the first dielectric member.

Particularly, the pressing mechanism has a member provided in contact with the metal electrode, and a bolt screwed into an insertion hole formed in the second dielectric member, to press the member interposed between the member and the metal electrode.

Particularly, the member is an elastic body.

Preferably, the opposing surface at the base portion of the first dielectric member is formed to have a recessed shape at the central portion along one direction of the metal electrode.

Preferably, the object of processing is inserted to a space between the two electrode units arranged opposite to each other.

According to the plasma processing apparatus of the present invention, at the electrode unit, thermal resistance between the cooling means and the sidewall portion of the first dielectric member is made higher than that between the cooling means and the base portion of the opposing surface facing the other electrode unit, of the first dielectric member, so as to reduce as much as possible the warp caused by temperature difference of the sidewall portion of the first dielectric member, whereby the warp at the base portion of the first dielectric member can be reduced. Thus, a plasma processing apparatus realizing high uniformity, hardly causing any influence on the distance between electrodes, can be provided.

According to another aspect, the present invention provides a plasma processing apparatus having two electrode units arranged opposite to each other and processing an object of processing with plasma generated between the two electrode units, wherein at least one of the two electrode units includes a metal electrode, a dielectric member provided to cover the metal electrode, and cooling means for cooling the dielectric member. The dielectric member has a base portion including an opposing surface facing the other electrode unit and a sidewall portion provided to cover, with the base portion, the metal electrode. Temperature difference between the opposing surface side and opposite side at the sidewall portion of the dielectric member is smaller than temperature difference between the opposing surface side and opposite, rear side at the base portion of the dielectric member.

According to the plasma processing apparatus of the present invention, at the electrode unit, temperature difference between the opposing surface side facing the other electrode unit and the opposite side at the sidewall portion of the dielectric member is made smaller than temperature difference between the opposing surface side facing the other electrode unit and the opposite, rear surface side at the base portion of the dielectric member, so as to reduce as much as possible the warp caused by the temperature difference at the sidewall portion of the dielectric member, whereby the warp at the base portion of the dielectric member can be reduced. Thus, a plasma processing apparatus realizing high uniformity, hardly causing any influence on the distance between electrodes, can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an illustration of a cross-section of the plasma processing apparatus in accordance with Embodiment 1 of the present invention.

FIG. 2 shows details of the electrode unit in accordance with Embodiment 1 of the present invention.

FIG. 3 illustrates relation between an approximately U-shaped dielectric and a metal electrode portion, of the electrode unit.

FIG. 4 shows points of temperature measurement of the approximately U-shaped dielectric and the metal electrode portion, of the electrode unit.

FIG. 5 plots relation between metal electrode length and amount of displacement.

FIG. 6 illustrates a structure of a part of the electrode unit in accordance with Embodiment 2 of the present invention.

FIG. 7 illustrates a structure of a part of the electrode unit in accordance with a modification of Embodiment 2 of the present invention.

FIG. 8 illustrates a structure of a part of the electrode unit in accordance with Embodiment 3 of the present invention.

FIG. 9 illustrates a dielectric in accordance with Embodiment 4 of the present invention.

### DESCRIPTION OF THE PREFERRED EMBODIMENTS

In the following, embodiments of the present invention will be described with reference to the figures. The present invention is not limited to the embodiments below.

### Embodiment 1

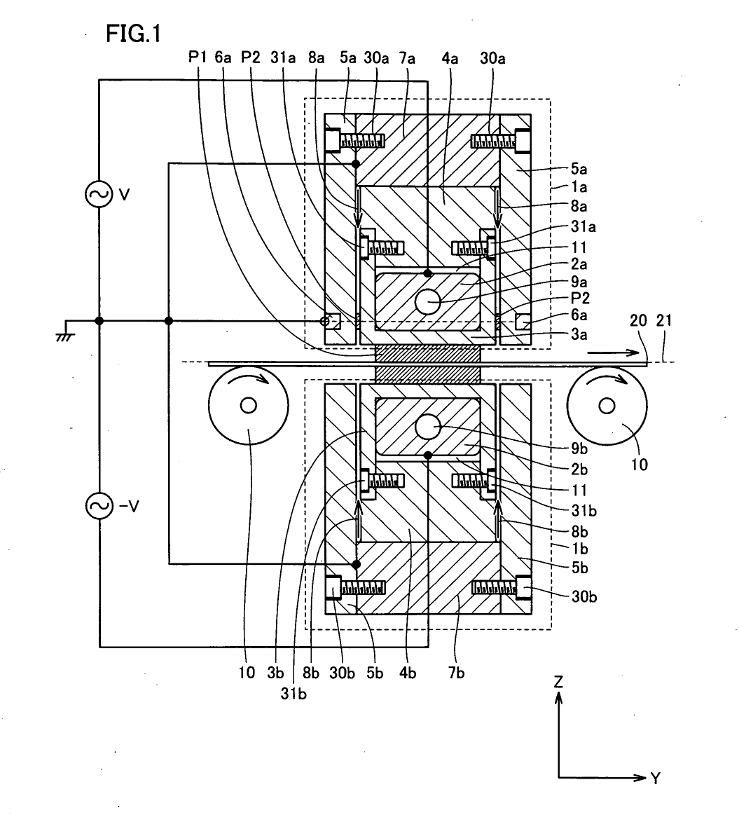

Referring to FIG. 1, a cross-section of the plasma processing apparatus in accordance with Embodiment 1 of the present invention will be described. The plasma processing apparatus in accordance with Embodiment 1 of the present invention is for in-line type substrate processing, or processing of a sheet-type or roll-type object and, here, a cross-section taken in the YZ direction is shown.

Referring to FIG. 1, the plasma processing apparatus in accordance with Embodiment 1 of the present invention is a counter electrode type apparatus consisting of electrode units 1a and 1b opposite to each other. Electrode units 1a and 1b are arranged vertically above (positive direction along the Z-axis) and vertically below (negative direction along the Z-axis) a surface 21 to be processed of an object substrate 20, respectively. The gap between electrode units 1a and 1b is selected and set to an appropriate value between 3 to 10 mm.

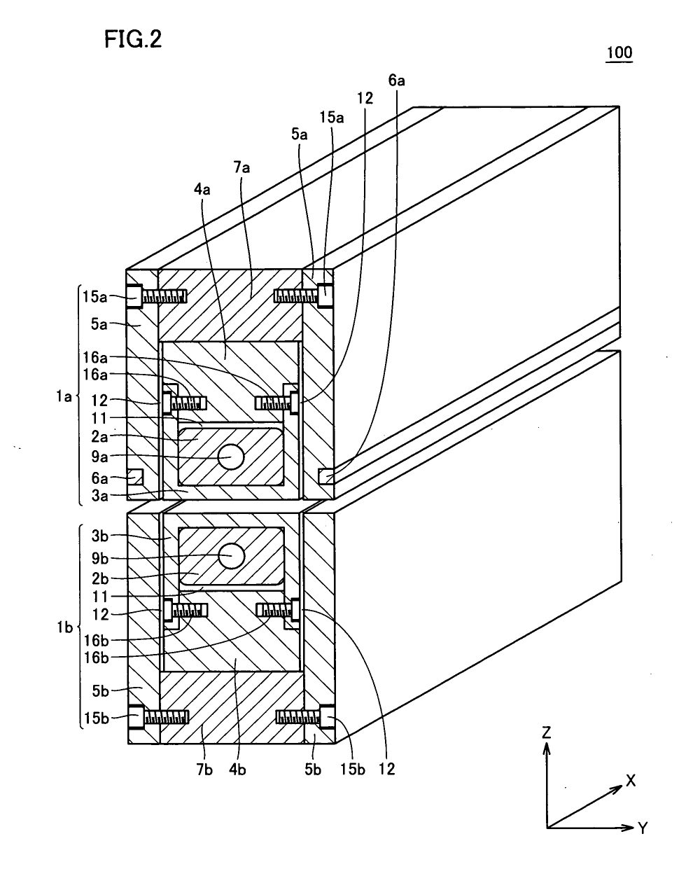

Next, referring to FIG. 2, electrode units 1a and 1b in accordance with Embodiment 1 will be described in detail. Electrode units 1a and 1b have substantially the same structure except for some points, arranged in plane-symmetry with respect to the X-Y plane.

Referring to FIG. 2, electrode units 1a, 1b in accordance with the present embodiment include: metal electrodes 2a, 2b; dielectrics 3a, 3b formed to have an approximately U-shape to cover metal electrodes 2a, 2b; dielectrics 4a, 4b of approximately T-shape combined with dielectrics 3a, 3b of approximately U-shape for tightly sealing metal electrodes 2a, 2b; metal electrodes 7a, 7b provided at upper and lower portions of dielectrics 4a, 4b, having a gas flow path formed inside; and dielectrics 5a, 5b having an approximately I-shape provided on opposite sides of each of the metal electrodes 7a, 7b. Different from electrode unit 1b, electrode unit 1a has a recess formed at a portion of dielectric 5a and a metal electrode 6a embedded in the recessed portion.

Inside metal electrodes 2a and 2b, cooling water passages 9a and 9b are provided for cooling the metal electrodes and the U-shaped dielectrics, which passages are each connected to a cooling water inlet and a cooling water outlet at opposite ends.

In the present embodiment, by way of example, a long metal electrode is used, and metal electrodes 2a and 2b are provided having the width representing dimension along Y-axis of 33 mm, height along Z-axis of 14 mm and length along X-axis of 2550 mm. Dielectrics 3a and 3b are formed to an approximately U-shape having the width of 42 mm, height of 30 mm and length of 2650 mm. Further, dielectrics 4a and 4b are formed to an approximately T-shape having the width of 42 mm, height of 30 mm and length of 2650 mm. Dielectrics 5a and 5b are formed to have an approximately I-shape having the width of 8 mm, height of 65 mm and length of 2650 mm. Metal electrode 6a is formed to have the width of 4 mm, height of 4 mm and length of 2750 mm. Cooling water passages 9a and 9b are formed to have a circular cross-section of the diameter of 8 mm. Cooling water passages 9a and 9b are provided with the center positioned at the height of 7 mm from the bottom surface portion of metal electrodes 2a and 2b.

Here, metal electrode 2a has four surfaces in the longitudinal direction covered by approximately U-shaped dielectric 3a and approximately T-shaped dielectric 4a, to prevent generation of arc discharge between metal electrodes. Where metal electrodes 6a and metal electrode 2a oppose to each other, approximately I-shaped dielectric 5a is provided. Where metal electrode 7a and metal electrode 2a oppose to each other, approximately T-shaped dielectric 4a is provided, to prevent generation of arc discharge as above. Substantially the same applies to electrode unit 1b.

The metal electrodes are formed of metal material having high electric conductivity such as aluminum (Al) or stainless steel (SUS), and the surfaces are subjected to surface processing such as alumite or alumina thermal spraying as needed, to prevent generation of arc discharge when there is a clearance between the electrode and the dielectric.

As the material of dielectrics, dielectric material having high dielectric constant and high coefficient of thermal conductivity, such as alumina or aluminum nitride is used.

Between the approximately I-shaped dielectric 5a and approximately U-shaped dielectric 3a, there is a clearance 12 of about 1 mm, allowing introduction of a process gas in the gas introducing directions 8a and 8b, as shown in FIG. 1.

Metal electrodes 2a and 2b are connected to have opposite phases to each other to high-voltage applying side of a high-frequency power source having the frequency of, for example, 30 kHz. Metal electrode 6a and metal electrodes 7a and 7b are connected to the ground side of the high-frequency power source.

Further, in electrode unit 1a, bolts 31a are screwed into bolt insertion holes, whereby the approximately U-shaped dielectric 3a is fixed to approximately T-shaped dielectric 4a. Bolts 30a are screwed into bolt insertion holes, whereby metal electrode 7a is fixed to approximately I-shaped dielectrics 5a on opposite sides. The same applies to electrode unit 1b.

Next, plasma processing using electrode units 1a and 1b will be described.

Though not shown, housings surround and support electrodes 1a and 1b. Under atmospheric pressure or near atmospheric pressure, a process gas, for example, a mixture of He=80 SLM, N₂=40 SLM, O₂=0.6 SLM, is continuously introduced to clearance 12 in the gas introduction directions 8a and 8b from a gas inlet for several 10 seconds, whereby the atmosphere around electrode units 1a and 1b is changed from air to process gas.

Thereafter, cooling water is caused to flow through cooling water passages 9a and 9b of electrode units 1a and 1b, and to metal electrodes 2a and 2b, a voltage of 7.5 kV at the frequency of 30 kHz is applied in opposite phases from the high-frequency power source, whereby a voltage of 15 kV is applied across metal electrodes 2a and 2b.

Then, at the gap between metal electrode 2a and metal electrode 6a, seed plasma P2 is generated and at the gap between metal electrodes 2a and 2b, main plasma P1 is generated. After such plasma generation, a substrate 120 as an object of processing having the size of 2100 mm×2400 mm×0.7 mm having a film of an organic such as a resist formed thereon, is inserted in-line through main plasma P1, between electrode units 1a and 1b, using a conveyer roller 10. This allows ashing of the resist of substrate 20 as the object of processing or processing of glass substrate portion to provide hydrophilic nature.

The performance of processing such as the amount of ashing of the electrode described above is determined by the type of process gas, ratio of components, total flow rate, frequency of high-frequency power source, power consumption by main plasma P1, length of metal electrodes 2a and 2b in the conveying direction, gap between electrode units, conveying speed of substrate as the object of processing, flow rate of process gas and the like.

Dependent on the performance of processing such as the required amount of ashing, an arrangement may be used in which a plurality of sets of electrode units described above are provided, or the width of metal electrodes 2a and 2b of electrode units 1a and 1b may be changed.

Here, by way of example, a so-called direct type plasma processing apparatus in which substrate 120 as an object of processing is passed between electrode units 1a and 1b will be described. It is noted, however, that the present invention is similarly applicable to a so-called remote type plasma processing apparatus in which plasma processing is executed with the object not passed directly between the electrode units.

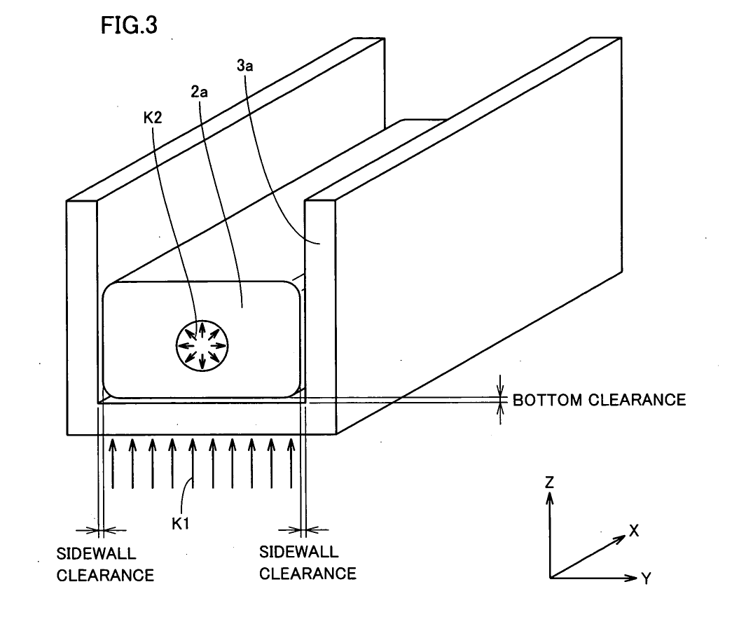

Referring to FIG. 3, the relation between metal electrode portion 2a and approximately U-shaped dielectric 3a of electrode unit 1a will be described. Though description will be given on electrode unit 1a in the following, the structure is substantially the same in electrode unit 1b and, therefore, detailed description thereof will not be repeated.

Here, mainly the electrode unit 1a will be described.

As shown in FIG. 3, in the plasma processing apparatus having the structure as described above, the side of approximately U-shaped dielectric 3a of electrode unit 1a facing the substrate as the object of processing (the side opposite to electrode unit 1b, that is, the side of plasma discharge surface) is directly exposed to main plasma P1 and seed plasma P2, and therefore, heat from the plasma increases its temperature.

Therefore, the side opposite to the surface of processing of dielectric 3a is designed to be as close as possible to metal electrode 2a, so that cooling water flowing inside metal electrode 2a opposite to the processing surface of dielectric 3a draws the introduced heat from the dielectric.

Because of the limit of processing accuracy, there may possibly be a clearance of about several to several hundreds μm (bottom clearance). Particularly, it is noted that metal electrode 2a is not fastened to the surrounding dielectric. Metal electrode 2a is so arranged as to abut the rear surface opposite to the plasma discharge surface of dielectric 3a because of its own weight, and a clearance may result because of warp or the like in the X direction (longitudinal direction of the electrode). The structure of electrode unit 1b is an upside-down version of electrode unit 1a and, therefore, metal electrode 3b is so arranged as to abut dielectric 4b because of its own weight. Therefore, though it depends on the accuracy of components, the bottom clearance tends to be larger than in electrode unit 1a.

Here, by way of example, in the structure shown in FIG. 1, in the region 11 between metal electrode 2a and dielectric 4a, a number of shim sheets of insulating material such as glass, Teflon® or fluoro-rubber having the thickness of several tens to several hundreds μm is inserted to press and adjust the bottom clearance to at most 20 μm, whereby the heat of dielectric is drawn away by the heat quantity of cooling water, and heat flux flowing between the bottom surface portion of dielectric 3a and metal electrode 2a increases. It is also possible to thinly apply adhesive between metal electrode 2a and the bottom surface side (bottom portion) of dielectric 3a.

Therefore, temperature difference generates between the front and rear surfaces at the bottom side (bottom portion), that is, the processing surface and the opposite surface, of approximately U-shaped dielectric 3a. The temperature difference leads to difference in the amount of thermal expansion at the front and rear sides of the dielectric. Therefore, considering the bottom portion only, larger warp in the Z direction is expected, with opposite ends in the X direction assumed to be fixed, as the approximately U-shaped dielectric 3a is long in the X direction.

In Embodiment 1, by way of example, at the sidewall portion (sidewall) of approximately U-shaped dielectric 3a, a heat insulator, a heat shield or an insulating material having small thermal conductivity is partially inserted to adjust the clearance to metal electrode 2a to be about 0.5 mm. Specifically, the sidewall portion of dielectric 3a and the metal electrode are set to be not in contact with each other, to reduce the heat flux flowing between the sidewall portion of dielectric 3a and metal electrode 2a.

In other words, thermal resistance between the sidewall portion of dielectric 3a and metal electrode 2a through which cooling water flows is set higher than thermal resistance between the bottom side of dielectric 3a and metal electrode 2a through which cooling water flows.

Utilizing such a structure, temperature difference in the Z direction (vertical direction) of the sidewall of approximately U-shaped dielectric 3a is made smaller than the temperature difference between the front and rear surfaces at the bottom (bottom portion) of approximately U-shaped dielectric 3a, whereby the warp in the Z direction at the sidewall portion of approximately U-shaped dielectric 3a is reduced. As a result, warp in the Z direction of the bottom portion of approximately U-shaped dielectric 3a continuous to the sidewall portion, is reduced.

Therefore, warp in the Z direction of dielectric 3a, which would be generated if the temperature difference only between the front and rear surfaces at the bottom were considered, can be curbed by utilizing the sidewall portion of U-shaped dielectric 3a.

The table below shows simulation results of thermal analysis using the plasma processing apparatus of FIG. 3 in accordance with Embodiment 1 of the present invention as a model.

TABLE 1

| | | | Result of Analysis | | | | | |
|---|---|---|---|---|---|---|---|---|
| | | | Bottom | Sidewall | | | | |
| | Parameter | | temp. | temp. | | | | |
| | Bottom | Sidewall | difference | difference | Displacement | Displacement | Displacement | Total |
| | clearance | clearance | T1 − T2 | T3 − T4 | in X direction | in Y direction | in Z direction | displacement |
| | d1 [mm] | d2[mm] | [° C.] | [° C.] | [μm] | [μm] | [μm] | [μm] |
| Embodiment | 0.02 | 0.5 | 5.4 | 0.5 | 477 | 8 | 603 | 769 |
| Comparative | 0.02 | 0.02 | 4.5 | 10.7 | 384 | 7 | 5058 | 5073 |
| Example 1 | | | | | | | | |
| Comparative | 0.50 | 0.02 | 0 | 34.1 | 948 | 17 | 17550 | 17575 |
| Example 2 | | | | | | | | |

In the simulation, only the main plasma P1 was considered as plasma, heat flux K1 of 3.8×104 W/m² was applied to the portion irradiated with main plasma P1, convection condition K2 was set at the cooling water passage portion of metal electrode 2a, convection coefficient was set to 3.0×103 W/m·K, and ambient temperature was set to 20° C. The values were determined based on the result of temperature measurement test actually performed in actual plasma processing.

Aluminum (Al) was used as the material of metal electrode 2a, and alumina of 99.5% was used for dielectric 3a, and physical property values such as thermal conductivity, Young's modulus and coefficient of linear expansion of respective materials were set. There is a clearance formed between metal electrode 2a and dielectric 3a, and thermal conductivity at the clearance is the thermal conductivity of air.

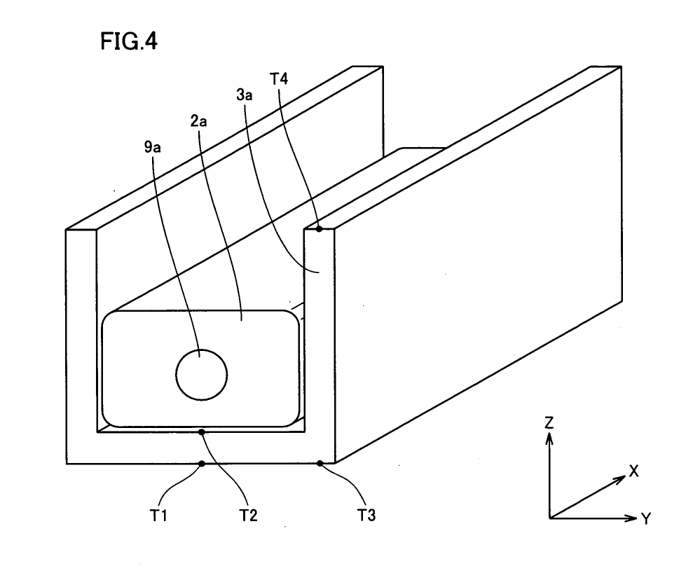

Referring to FIG. 4, points of temperature measurement on metal electrode 2a and dielectric 3a of electrode unit 1a will be described.

Referring to FIG. 4, temperatures at the front and rear portions of the bottom of dielectric 3a will be denoted as T1 and T2. Temperature T1 denotes the temperature of dielectric 3a at the plasma discharge surface side of the bottom portion. Temperature T2 denotes the temperature of dielectric 3a at the rear surface opposite to the plasma discharge surface, of the bottom portion. Temperatures T3 and T4 denote temperatures on the plasma discharge surface side and the opposite side, of the sidewall portion of dielectric 3a. Here, temperature difference at the bottom portion will be given as T1−T2, and the temperature difference at the sidewall portion will be given as T3−T4.

Thermal analysis was performed using bottom clearance d1 and sidewall clearance d2, representing the clearance at the sidewall portion, as parameters.

Representative examples of analysis will be described in the following.

As the example in accordance with the embodiment, also considering the result of temperature measurement, the bottom clearance d1 was set to 0.02 mm and the sidewall clearance d2 was set to 0.5 mm (of the values above, actually, the bottom portion was almost in contact; the clearance was determined to be consistent with the actual result of temperature measurement and, hence it was set not to 0 but to 0.02 mm).

As shown in the Table, the temperature difference at the bottom (T1−T2) was 5.4° C., while the temperature difference in the vertical direction of the sidewall portion (T3−T4) was 0.5° C., and therefore, the amount of displacement of dielectric 3a in the Z direction was 603 μm and even in the long electrode having the length of 2650 mm, the amount of change in the gap between electrodes could be made as small as about 1 mm.

As Comparative Example 1, thermal analysis simulation was performed on an example in which bottom clearance d1 was 0.02 mm and sidewall clearance d2 was 0.02 mm, that is, metal electrode 2a and dielectric 3a were substantially in contact with each other. As Comparative Example 2, thermal analysis simulation was performed on an example in which bottom clearance d1 was 0.5 mm and sidewall clearance d2 was 0.02 mm, that is, metal electrode 2a was substantially in contact with only the sidewall portion of dielectric 3a.

Comparative Example 1 is different from the example of the embodiment only in the sidewall clearance d2. Here, as the clearance d2 at the sidewall portion is small, the sidewall portion of dielectric 3a is cooled by metal electrode 2a, and temperature difference of sidewall portion in the vertical direction of dielectric 3a becomes 10.7° C. Therefore, though the temperature difference (T1−T2) at the bottom portion is not much different between the example of the embodiment and Comparative Example 1, the amount of displacement in the Z direction of Comparative Example 1 exceeds 5 mm, which is more than 8 times the amount of displacement in the Z direction of the example in accordance with the embodiment. If the gap distance between the electrodes is about 10 mm, the gap would be eliminated at the central portion of electrodes where the amount of warp becomes considerable, and according to the result, the structure would not attain the function of a plasma processing apparatus.

In Comparative Example 2 in which bottom clearance d1 is 0.5 mm and sidewall clearance d2 is 0.02 mm, cooling by metal electrode 2a hardly takes place at the bottom portion of dielectric 3a, while the sidewall portion is cooled. Therefore, temperature difference at the sidewall portion of dielectric 3a becomes as large as 34.1° C., and the amount of displacement in the Z direction is 29.1 times larger than in the example of the embodiment. The amount of warp is as large as 17 mm or larger, and according to the results, the structure cannot attain the function of a plasma processing apparatus.

By changing the thermal resistance between metal electrode 2a having the cooling water passage and the bottom portion and sidewall portion of dielectric 3a, it becomes possible to curb warp at the sidewall portion of dielectric 3a and to make smaller the warp at the bottom portion of dielectric 3a. As a result, fluctuation in distance between the electrodes can be made smaller and highly uniform plasma generation becomes possible.

Referring to FIG. 5, relation between the length of metal electrode and the amount of displacement will be described.

FIG. 5 shows the amount of displacement of dielectric 3a in the Z direction, when the thermal analysis described above was executed, with the length of metal electrode in the longitudinal direction (X direction) varied.

Referring to the figure, in Comparative Example 1, the amount of displacement of the dielectric in the Z direction increases in proportion to the square of metal electrode length. Specifically, as the length of metal electrode increases, amount of displacement of the dielectric increases and eventually process uniformity would be lost, unless the clearance and thermal resistance are maintained appropriately so that the heat flux flowing between the bottom surface of dielectric 3a and metal electrode 2a becomes higher than the heat flux flowing between the sidewall portion of dielectric 3a and metal electrode 2a. Particularly in a long metal electrode of 1000 mm (1 m) or longer, the amount of displacement in the Z direction much increases and exceeds the tolerable range of displacement considering the distance between electrodes, and the influence of displacement in the Z direction would be significant.

In the example in accordance with the present embodiment, even in a long metal electrode of 1000 mm (1 m) or longer, the amount of displacement is within the tolerable range, allowing uniform plasma processing.

Therefore, thermal analysis simulation proved that, by the structure of the present embodiment, the amount of warp of the dielectric could considerably be curbed particularly in a long electrode of 1 m or longer, and a plasma processing apparatus for processing a substrate of large size could be provided. In the thermal analysis simulation described above, thermal conductivity of the clearance between meal electrode 2a and dielectric 3a is calculated as thermal conductivity of air, assuming that the clearance is a vacant space. Similar effect can be expected if a heat insulator or heat shield having small thermal conductivity, such as a plate material, glass or resin material is inserted or if the sidewall portion is surface-processed with a material having small thermal conductivity and calculation is done using the thermal conductivity of such material. A structure having a heat insulating portion or a heat shield portion provided on the metal electrode may also be possible. Here, the heat insulator or heat shield inserted between metal electrode 2a and the sidewall portion of dielectric 3a, the material of surface-processing or the heat insulating portion provided on the metal material should preferably have thermal conductivity smaller than that of dielectric 3a.

As regards the clearance between metal electrode 2a and dielectric 3a, what is necessary is that the bottom clearance between metal electrode 2a and the bottom portion of dielectric 3a is made narrower than the clearance between metal electrode 2a and the sidewall portion of dielectric 3a as a whole, so that heat flux flowing between the bottom portion of dielectric 3a and metal electrode 2a becomes higher than the heat flux flowing between the sidewall portion of dielectric 3a and metal electrode 2a as a whole and that thermal resistance between the cooling means (in the embodiment, metal electrode having the cooling water passage) and the sidewall portion of dielectric 3a becomes higher than the thermal resistance between the cooling means and the bottom portion of dielectric 3a, and the state of contact or non-contact in the strict sense is not always necessary. By way of example, even when metal electrode 2a is partially in contact with the sidewall portion of dielectric 3a, the components may be considered as in non-contact state as a whole. On the other hand, even when a thin adhesive layer is interposed between metal electrode 2a and the bottom portion of dielectric 3a, the components may be considered as in contact with each other. In other words, the in-contact state or non-contact state refers to relative relation of narrow or wide as to the distance between metal electrode 2a and the bottom portion of dielectric 3a or between metal electrode 2a and the sidewall portion of dielectric 3a.

The cooling water passage is not limited to the structure described above, and preferably it is provided at a position close to the bottom portion as the plasma discharge surface of dielectric 3a as the heat source. Though a structure in which one cooling water passage is provided in metal electrode 2a has been described, not one but a plurality of cooling water passages may be provided. Further, the cross-sectional shape is not limited to a circle and it may be rectangular, to enlarge surface area. Though a structure in which the cooling water passage is provided in metal electrode 2a to cool metal electrode 2a from the inside has been described, the structure is not limited to one in which the cooling water passage is provided in the metal electrode. By way of example, a structure having metal electrode 2a and a pipe of cooling water passage provided in contact with each other to cool the metal electrode from outside may be possible. Though cooling by water has been described above, cooling means using gas or the like may be used. Further, the cooling means may be provided on dielectric members 3a and 3b.

Further, the present invention attains similar effects as described above by the reduction of warp amount of the dielectric, even when the electrodes are not longer than 1 m but the gap between electrodes is narrow or when the pressure is low but the gap between electrodes is narrow. Though an example in which the gap between electrodes is narrow has been described in the embodiment to illustrate the distinctive effect, the present invention clearly has the effect of attaining uniform plasma processing even when the gap is wide. Further, it is also effective to prevent damage to the dielectric caused when the warp amount of dielectric is large.

Thought an example in which electrode units 1a and 1b have identical structure has been described in the embodiment, the structure is not limited and it is sufficient if at least one electrode unit has the structure of the present invention. Though an example in which electrode units 1a and 1b are arranged opposite to each other vertically has been described, the arrangement is not limited and the units may be arranged opposite to each other in the horizontal direction.

Though an example in which the present invention is applied to an ashing apparatus has been described in the embodiment, it is not limiting and the invention may also applicable to various plasma processing apparatuses such as an etching apparatus, a surface-processing apparatus and a film forming apparatus.

### Embodiment 2

In Embodiment 2 of the present invention, another method of reducing bottom clearance d1 will be described.

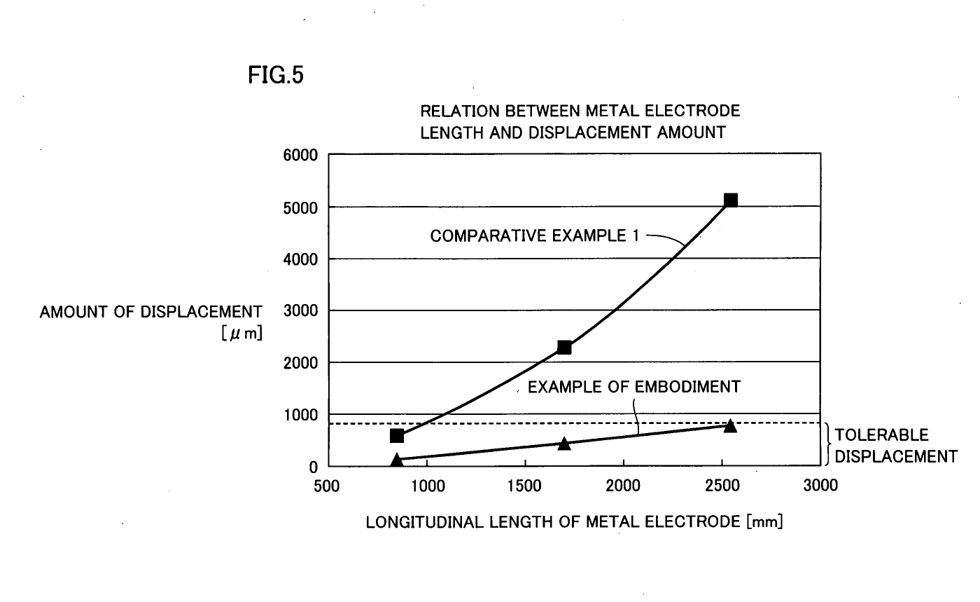

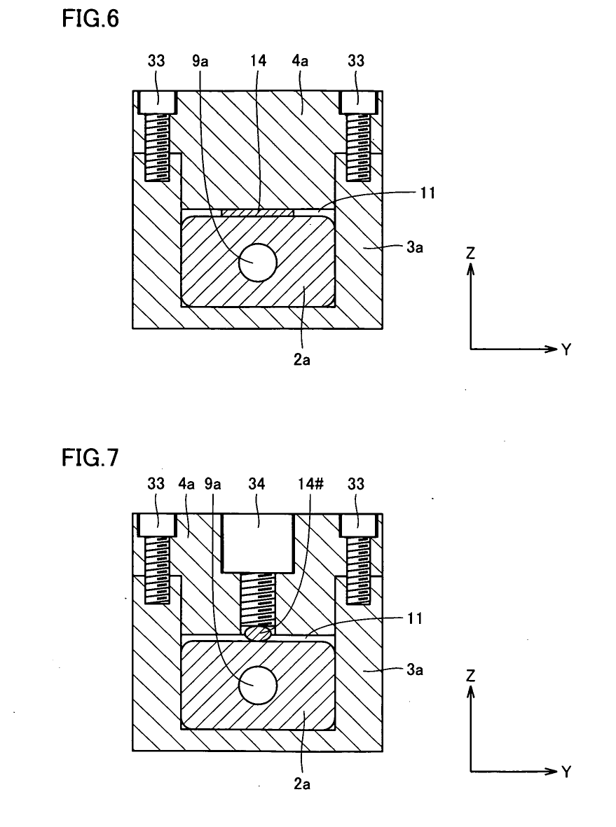

Referring to FIG. 6, a partial structure of electrode unit 1a in accordance with Embodiment 2 of the present invention will be described.

Here, a cross-section along a YZ plane of a main portion is shown. In a region 11, a sheet-shaped elastic body 14 is inserted such that metal electrode 2a comes as close as possible to the inner bottom surface of U-shaped dielectric 13a. Then, in order to fasten T-shaped dielectric 4a to U-shaped dielectric 3a, a bolt insertion hole is provided and a bolt 33 is screwed in, so that the dielectrics are fastened by the bolt in Z direction.

In Embodiment 1, a method of adjusting bottom clearance d1 by inserting a shim has been described. By the structure described above, the clearance can further be adjusted delicately by utilizing elasticity of elastic body 14 and fastening by bolt 33. Here, bolt 33 and elastic body 14 constitute a pressing mechanism pressing metal electrode 2a to the base portion of U-shaped electrode 3a.

Therefore, thermal conductivity of dielectric 3a and metal electrode 2a can be made lower than in Embodiment 1, and hence, the temperature of plasma irradiation surface of dielectric 3a can be made lower, temperature difference in dielectric 3a as a whole can be made smaller, and hence, the amount of warp of dielectric 3a can be made smaller. When the thermal analysis simulation as described above is performed applying the electrodes of this structure to the plasma processing apparatus, difference in the gap between electrodes in the lengthwise direction, that is, X axis direction of the electrodes could be made to 1 mm or smaller, and even when the gap between electrodes is about 4 mm, uniformity of at most 15% could be attained and uniform processing could be executed. The pressing mechanism pressing metal electrode 2a to the base portion of U-shaped dielectric 3a may also be used when a filler or inclusion such as a shim is inserted.

### Modification of Embodiment 2

In a modification of Embodiment 2, a still further method of reducing bottom clearance d1 will be described.

Referring to FIG. 7, a partial structure of electrode unit 1a in accordance with the modification of Embodiment 2 will be described.

Here, a cross-section along a YZ plane of a main portion is shown. In region 11, a spherical-shaped elastic body 14# is inserted such that metal electrode 2a and the inner bottom surface of U-shaped dielectric 13a come to be in contact as much as possible with each other. As compared with the structure of FIG. 6, a plurality of insertion holes are additionally formed vertically in the longitudinal direction of T-shaped dielectric 4a, bolt 34 formed of dielectric is inserted to each hole, and spherical elastic body 14# is pressed, whereby metal electrode 2a and the inner bottom surface of U-shaped dielectric 3a can be brought into contact with each other, utilizing elasticity of elastic body 14#. By such an arrangement, the bottom clearance can be made smaller than the example of Embodiment 1 in which shim of non-elastic material is inserted. Here, bolt 34 and elastic body 14# constitute the pressing mechanism pressing metal electrode 2a to the base portion of U-shaped dielectric 3a.

In this manner, the surface temperature of the dielectric can be lowered, and temperature difference of the dielectric as a whole can be reduced, whereby the amount of warp of the dielectric can be made smaller. By applying the electrodes of this structure to the plasma processing apparatus, difference in the gap between electrodes in the lengthwise direction can be made to 1 mm or smaller and, even when the gap between electrodes is about 4 mm, and uniform processing with uniformity of at most 15% becomes possible.

### Embodiment 3

In the foregoing, a structure in which metal electrode 2a is covered by a combination of T-shaped dielectric and U-shaped dielectric has been described. Use of U-shaped or T-shaped dielectric, however, is not limiting and combination of various shapes of dielectrics or combination of a plurality of dielectrics may be possible.

Referring to FIG. 8, a partial structure of electrode unit 1a in accordance with Embodiment 3 will be described. Here, a cross-section along a YZ plane of a main portion is shown.

Referring to FIG. 8, specifically, an example is shown in which metal electrode 2a, an approximately flat dielectric 3# and dielectrics 3#a and 3#b formed to have an approximately inverted L-shape are combined. Here is shown an example in which, by providing a bolt insertion hole and screwing bolt 35 therein, dielectrics 3#a and 3#b are fastened to each other, and by providing a bolt insertion hole and screwing bolt 36 therein, approximately flat dielectric 3# and dielectrics 3#a and 3#b are fastened.

In this example, as shown, a shim may be inserted to region 11 and by screwing bolt 36, bottom clearance d1 may be adjusted.

Similar to the structures described above, in the structure of Embodiment 3, it is possible to attain the state of good thermal conduction by making smaller the clearance at the portion fastening dielectrics to each other.

By applying the electrodes of such structure to a plasma processing apparatus, amount of displacement of the dielectric can be made smaller as in the foregoing.

### Embodiment 4

In Embodiments 1 to 3, methods of reducing amount of displacement of the dielectric have been described. In Embodiment 4, a method of correcting the gap between electrode units will be described.

Long dielectric 3a or 3b having the length of 2650 mm inevitably warps in the longitudinal direction, even when the temperature difference at the sidewall portion is made as small as possible. Specifically, on the side of plasma irradiation surface, at the central portion of the electrode unit along the X-axis, convex deformation of several hundreds μm is possible. In such a case, the smaller the gap between electrode units, the larger the influence by the deformation becomes, making uniform plasma processing difficult.

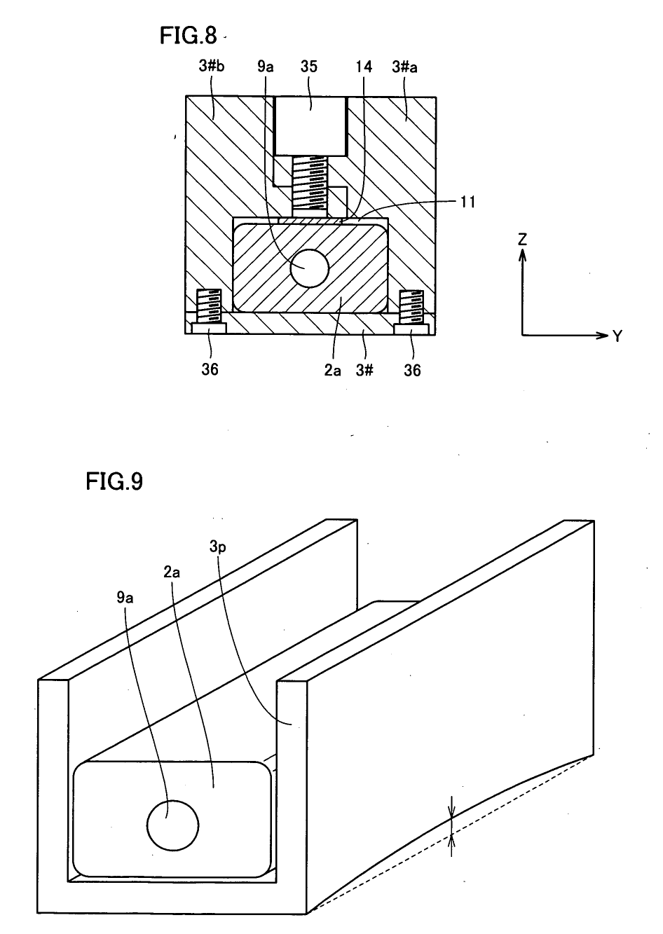

Referring to FIG. 9, a dielectric 3p in accordance with Embodiment 4 will be described.

Referring to FIG. 9, dielectric 3p is processed and formed such that the central portion in the longitudinal direction of the plasma irradiation surface is recessed by about several hundreds μm than end portions, considering beforehand the amount of deformation at the time of plasma irradiation. A plasma apparatus is fabricated using dielectric 3p as such, so that the plasma irradiation surface becomes flat when deformed because of the difference of thermal expansion at the time of plasma irradiation. With such an arrangement, the thermal analysis simulation described above was performed, and the gap length was substantially constant over the longitudinal direction, and highly uniform plasma processing with the uniformity of at most 10% in the plane of substrate 120 of 2100 mm×2400 mm was possible.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A plasma processing apparatus having two electrode units arranged opposite to each other and processing an object of processing with plasma generated between said two electrode units, wherein
at least one of said two electrode units includes
a metal electrode,
a first dielectric member provided to cover said metal electrode, and
cooling means for cooling said first dielectric member;
said first dielectric member has a base portion including an opposing surface facing the other electrode unit and a sidewall portion provided to cover, with said base portion, said metal electrode; and
thermal resistance between the sidewall portion of said first dielectric member and said cooling means is higher than thermal resistance between the base portion of said dielectric member and said cooling means.

2. The plasma processing apparatus according to claim 1, wherein
said cooling means corresponds to a passage of a cooling medium provided for said metal electrode.

3. The plasma processing apparatus according to claim 2, wherein
between the sidewall portion of said first dielectric member and opposing said metal electrode, a heat insulator is inserted.

4. The plasma processing apparatus according to claim 1, wherein
a clearance between a rear side opposite to said opposing surface at the base portion of said first electrode member and opposing said metal electrode is narrower than a clearance between a surface opposing to said metal electrode of the sidewall portion of said first dielectric member and said metal electrode.

5. The plasma processing apparatus according to claim 1, wherein
the rear side opposite to said opposing surface at the base portion of said first electrode member and opposing said metal electrode are in contact with each other; and
the surface opposing to said metal electrode of the sidewall portion of said first dielectric member and said metal electrode are not in contact with each other.

6. The plasma processing apparatus according to claim 1, wherein
said first dielectric member has a U-shaped cross section having said base portion and said sidewall portion.

7. The plasma processing apparatus according to claim 1, wherein
said electrode unit further includes
a second dielectric member provided to cover, in combination with said first dielectric member, said metal electrode, and
a pressing mechanism for pressing said metal electrode to the rear surface opposite to said opposing surface, at the base portion of said first dielectric member.

8. The plasma processing apparatus according to claim 7, wherein
said pressing mechanism has
a member provided in contact with said metal electrode, and
a bolt screwed into an insertion hole formed in said second dielectric member, to press said member interposed between said member and said metal electrode.

9. The plasma processing apparatus according to claim 8, wherein
said member is an elastic body.

10. The plasma processing apparatus according to claim 1, wherein
said opposing surface at the base portion of said first dielectric member is formed to have a recessed shape at the central portion along one direction of said metal electrode.

11. The plasma processing apparatus according to claim 1, wherein
said object of processing is inserted to a space between said two electrode units arranged opposite to each other.

12. A plasma processing apparatus having two electrode units arranged opposite to each other and processing an object of processing with plasma generated between said two electrode units, wherein
at least one of said two electrode units includes
a metal electrode,
a dielectric member provided to cover said metal electrode, and
cooling means for cooling said dielectric member;
said dielectric member has a base portion including an opposing surface facing the other electrode unit and a sidewall portion provided to cover, with said base portion, said metal electrode; and
temperature difference between said opposing surface side and opposite side at the sidewall portion of said dielectric member is smaller than temperature difference between said opposing surface side and opposite, rear side at the base portion of said dielectric member.
